(19) United States
(12) Patent Application Publication
(10) Pub. No.: US 2012/0162932 A1
(43) Pub. Date: Jun. 28, 2012

(54) POWER AND GROUND PLANES HAVING MODIFIED RESONANCE FREQUENCIES

(76) Inventors: JOHN T. CONTRERAS, Palo Alto, CA (US); ALBERT J. WALLASH, Morgan Hill, CA (US)

(21) Appl. No.: 12/976,875

(22) Filed: Dec. 22, 2010

(51) Int. Cl. H05K 1/18; H05K 1/16

(52) U.S. Cl. 361/748; 174/260

(57) ABSTRACT

Adjusting the resonance of a power distribution network in a device to ensure a resonance frequency of the device is outside of a frequency band of wireless signals, other interference signals, or interference signals intrinsic to the device. The resonance frequency may be adjusted by cutting slices into the power and/or ground planes such that a serpentine pattern (or other desired pattern) is formed. The serpentine pattern increases the length that the current travels along the power/ground plane and thus, changes the resonance frequency of the device.

### BACKGROUND OF THE INVENTION

1. Field of the Invention

Embodiments of the present invention generally relate to a power or ground plane designed to have a resonance frequency outside of wireless frequency bands.

2. Description of the Related Art

Network connectivity is a basic feature of computers. While some computers connect to a network through an Ethernet connection, many computers (in particular portable computers such as laptops, notebooks and smart phones) establish network connections utilizing a wireless connection through a mobile telephone network. A wireless signal transmits between the network provider and the computer at a frequency. For third generation mobile telephone signals (3G), the frequency is around 1.8 GHz+/−100 MHz for the Enhanced Date for GSM Evolution (EDGE) band and around 900 MHz+/−100 MHz for the General Packet Radio Service (GPRS) band.

These operating frequencies may pose a problem with respect to power distribution networks by which power from a power source is transmitted to the various components of a computer. An example of a power distribution network is shown in FIGS. 1A and 1B. FIG. 1A is a cross sectional view of the power distribution network 100 and FIG. 1B is a top view of the power plane 106. The power distribution network 100 includes a ground plane 102 and a power plane 106 that are electrically isolated from each other by a dielectric layer 104. Both the power plane 106 and the ground plane 102 have a resonance frequency. If the power and/or ground plane is improperly designed, the resonance frequency may be close to or at the 3G frequency. Thus, the power distribution network may interfere with the wireless signal provided by the mobile telephone network.

FIG. 2 shows an example of a power plane 202 for a hard disk drive. For the power plane 202, there are strong resonances at 930 MHz and at 1.8 GHz as shown in FIG. 3, which interfere with GPRS and EDGE bands. Thus, due to the electronic interference accentuated by the resonance frequency of the power plane, the computer may be unable to connect wirelessly to a network node, such as a wireless router or cell tower.

### SUMMARY OF THE INVENTION

Embodiments of the present invention generally relate to adjusting the resonance of a power distribution network in devices to ensure the resonance frequency is outside of the frequency band of wireless signals used to access a wireless network. The resonance frequency is adjusted by forming openings in the power and/or ground planes to form a pattern that produces a desired resonance frequency. For example, the openings may form a pattern, such as a serpentine pattern. The serpentine pattern increases the length that the current travels along the power/ground plane and thus, changes the resonance frequency of the device.

In one embodiment, a printed circuit board (PCB) power/ground plane includes a main portion and a new resonance modification element that extends from the main portion provisioned with a plurality of interleaved and parallel openings to form a serpentine path from a first end of the element to a second end of the element. The configuration of the openings is selected to achieve a desired resonance frequency different from an undesired resonance frequency produced by the modification element in the absence of the openings.

In another embodiment, a device includes a wireless card and a power/ground plane. The power/ground plane includes a body extending from a first end to a second end, wherein the body has a plurality of interleaved slices formed therein to create a serpentine pattern that alters the resonant frequency of the body relative to the resonant frequency of the body in absence of the plurality of interleaved slices.

In another embodiment, a device includes a wireless card and a hard disk drive having a power/ground plane. The power/ground plane includes a body extending from a first end to a second end, wherein the body has a plurality of interleaved slices formed therein to create a serpentine pattern that alters the resonant frequency of the body relative to the resonant frequency of the body in absence of the plurality of interleaved slices.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A and 1B are schematic illustrations of a power distribution network.

FIG. 2 is a schematic isometric view of a prior art power plane.

FIG. 3 is a graph showing the resonance frequency of the power plane of FIG. 2.

FIG. 4A is a schematic illustration of a generic power plane 400.

FIG. 4B is a schematic illustration of power plane 400 having a plurality of interleaved slices 406 formed therein.

FIG. 5 is a schematic isometric view of a power plane that has been modified to include a plurality of parallel slices.

FIG. 6 is a graph showing the resonance frequency of the power plane of FIG. 5.

FIG. 7 is a schematic isometric view of a power plane that has bee modified to include a plurality of parallel slices according to another embodiment.

FIG. 8 is a schematic illustration of a SOC coupled to a power plane.

FIG. 9 is a graph showing the GTEM emissions for the SOC coupled to the power plane of FIG. 8.

FIG. 10 is a schematic illustration of a computer that may incorporate the embodiments discussed herein.

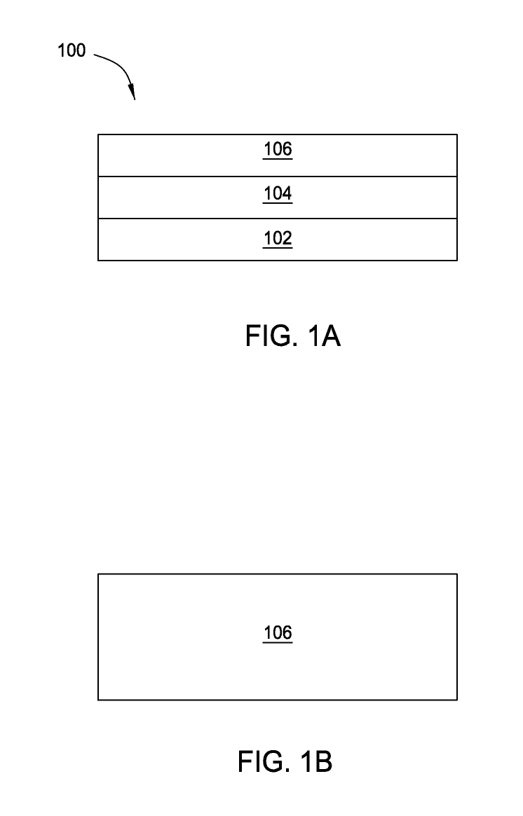

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

In the following, reference is made to embodiments of the invention. However, it should be understood that the invention is not limited to specific described embodiments. Instead, any combination of the following features and elements, whether related to different embodiments or not, is contemplated to implement and practice the invention. Furthermore, although embodiments of the invention may achieve advantages over other possible solutions and/or over the prior art, whether or not a particular advantage is achieved by a given embodiment is not limiting of the invention. Thus, the following aspects, features, embodiments and advantages are merely illustrative and are not considered elements or limitations of the appended claims except where explicitly recited in a claim(s). Likewise, reference to “the invention” shall not be construed as a generalization of any inventive subject matter disclosed herein and shall not be considered to be an element or limitation of the appended claims except where explicitly recited in a claim(s).

Embodiments of the present invention generally relate to adjusting the resonance of a power distribution network in devices to ensure the resonance frequency is outside of the frequency band of wireless signals used to access the internet or other wireless communication signal, and/or to move the resonance frequencies outside of the frequency band of the interference signal extrinsic or intrinsic to the power-plane structure. The resonance frequency is adjusted by forming openings (e.g. cutting slices) into the power and/or ground planes such that a desired pattern is formed to alter the resonance frequency. The pattern (e.g. serpentine pattern) increases the length that the current travels along the power/ground plane and thus, changes the resonance frequency of the device.

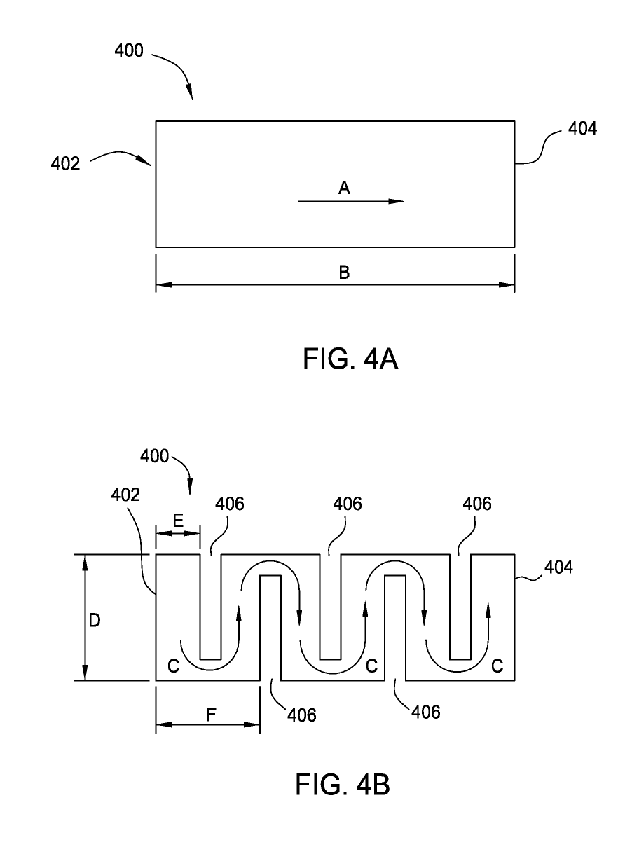

FIG. 4A is a schematic illustration of a generic power plane 400. FIG. 4B is a schematic illustration of the power plane 400 having a plurality of interleaved slices 406 cut therein. In the embodiment shown in FIG. 4A, the electrical current simply flows unimpeded from the first end 402 to the second end 404 of the power plane in the direction shown by arrow “A”. Thus, the electrical current flows for a distance represented by arrow “B”, which is the length of the power plane. As discussed above, the power plane 400 has a resonance frequency.

Once the slices 406 are formed in the power plane 400, the electrical current must travel a greater distance than simply the length of the power plane to go from the first end 402 to the second end 404, which lowers the resonance frequency by increasing the propagation delay of the power-plane structure. The electrical current must flow around the slices 406 as shown by arrows “C” in a serpentine pattern and therefore travel a greater distance than traveled in FIG. 4A. Therefore, the resonance for the power plane 400 in FIG. 4B has been changed from the value of the resonance of the power plane 400 in FIG. 4A that does not have the slices 406.

The slices 406 are, in essence, a plurality of interleaved and parallel openings that form a serpentine path from the first end 402 to the second end 404. The configuration of the slices 406 is selected to achieve a desired resonance frequency that is different from the undesired resonance frequency of the power plane 400 in absence of the slices 406.

In one aspect, the slices 406 ensure that the power plane 400 does not have a resonance frequency that interferes with the 3G signal to the computer (i.e., an undesired resonance frequency). The provision of the slices 406 may be particularly advantageous where changing the size and shape of the power plane 400 may not be practical due to the layout of the printed circuit board. Therefore, where the same basic layout of the power plane is necessary the shape and size of the slices may be selected to preserve that layout. Specifically, the slices 406, when added to the power plane, increase the length that the current has to travel from one end 402 to the other end 404 while maintaining the same basic layout, size and shape of the power plane 400. Increasing the length that the current travels increases the propagation delay and changes the resonance frequency of the power plane 400. In particular, the slices 406 shift the resonance frequency to a frequency range that does not interfere with the frequency range at issue, e.g., the 3G range. It is to be understood that the slices 406 may be tailored to be in a particular location or of particular dimensions (width and/or length) to adjust the resonance frequency to a value that is not only outside of the 3G range, but outside any specified range.

The number of slices 406 and the depths of the slices 406 may be predetermined based upon a mathematical model. The slices 406 create semi-rectangular blocks that have a height shown by arrows “D” and a width as shown by arrows “E”. The slices 406 create the serpentine pattern that shortens the distance shown by arrows “F” that the electrical current may travel in the direction that is perpendicular to the ends 402, 402 of the power plane 400. The serpentine length directly relates to the resonance frequency, so the length is set such that resonance out of the frequency range of interest. The resonance frequency is determined by the transmission line equation for the quarter-wave length resonance (fo=length/(4*velocity), where velocity is for the power plane, typically ⅔*speed of light).

It is to be understood that while the description is made with reference to a power plane, the embodiments are equally applicable to the ground plane because the ground plane will also have a resonance. In one embodiment, the ground plane will have the same shape as the power plane as well as the same slice layout. In another embodiment, the ground plane will have the same shape as the power plane yet have a different slice layout. In another embodiment, the ground plane will have the same shape as the power plane yet have no slices. In another embodiment, the ground plane will have a different shape than the power plane and have a different slice layout. In another embodiment, the ground plane will have a different shape than the power plane yet have no slices. Additionally, it is to be understood that the power distribution network discussed is not limited to a power distribution network of a printed circuit board of a hard disk drive, but rather, equally applies to a power distribution network of a printed circuit board used in a computer.

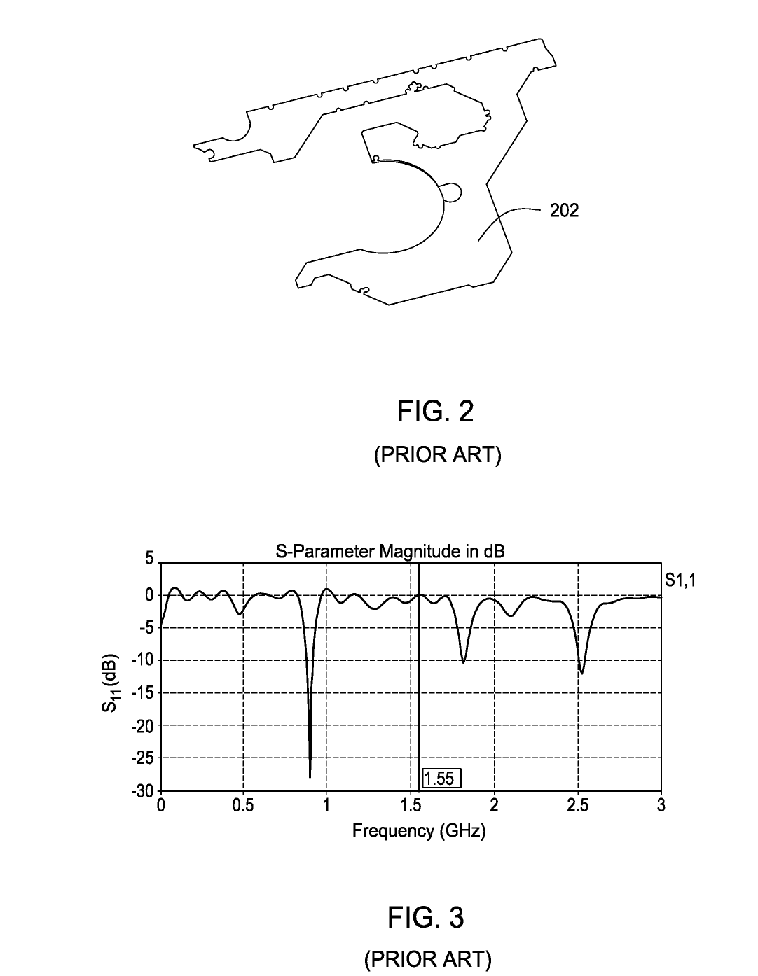

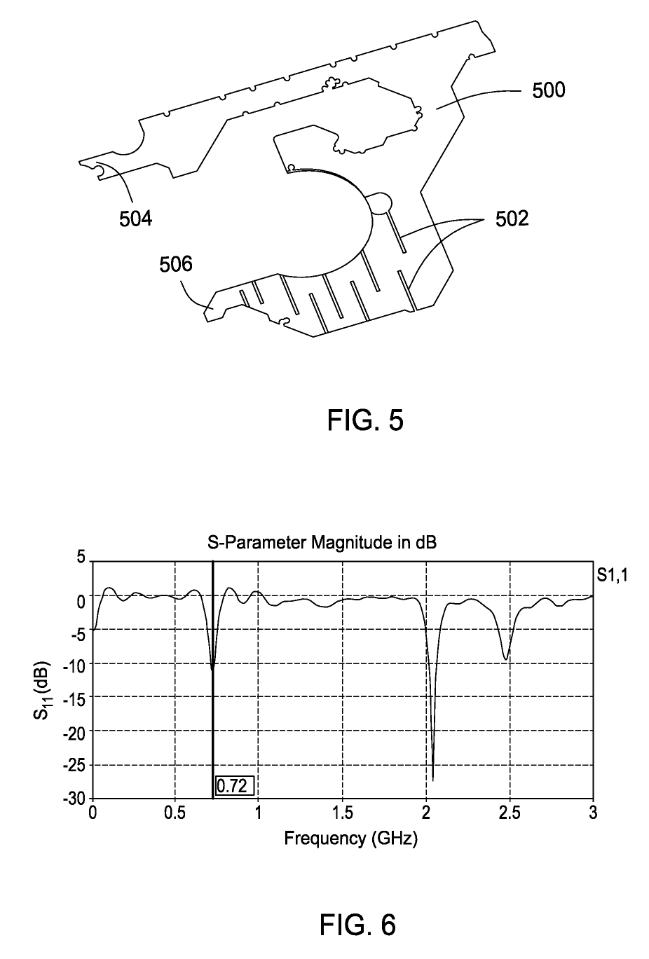

FIG. 5 is a schematic isometric view of a power plane 500 that has been modified to include a plurality of parallel slices 502 that change the resonance of the power plane 500. For comparison purposes, the power plane 500 has the same shape and size as the power plane 202 of FIG. 2. In the embodiment of FIG. 5, the slices 502 are present at a location closer to the second end 506 of the power plane 500 than the first end 504 where the power supply will couple to the power plane 500. Thus, the slices 502 closer to the second end create a new resonance modification element for the power plane 500. As shown in FIG. 6, the power plane 500 has a resonance frequency around 720 MHz and around 2.1 GHz, both of which are outside of both the EDGE and GRPS frequencies. Thus, the resonance frequencies of the power plane 500 have been changed relative to the power plane 202 of FIG. 2 due to the slices 502.

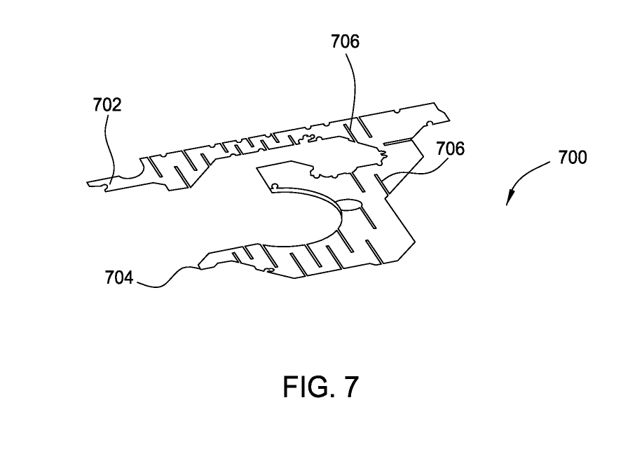

While the slices 502 are shown closer to one end of the power plane 500 in FIG. 5, it is to be understood that the slices need not be simply at one end of the power plane, but rather, the slices 706 may be made over the entire power plane 700 as shown in FIG. 7. For comparison purposes, the power plane 700 has the same shape and size as the power plane 202 of FIG. 2 and the power plane 500 of FIG. 5. The key is to place the slices where a significant amount of current flows. For example, if a large amount of current is present at a location closer to the second end 704 of the power plane 700 than the first end 702, then slices 706 will have a greater effect closer to the second end 704 rather than the first end 702. Similarly, if there is little or no current flowing at a portion of the power plane, slices will have little if any effect if placed in the portion having little or no current. In essence, the slices help to change the location of the standing wave.

The geometry of the power plane will dictate the resonance frequency of the power plane. Therefore, any power plane (or ground plane) may have its resonance frequency adjusted based upon the geometry of the power plane. For example, printed circuit boards in different laptop computers have different geometries and thus, different resonance frequencies. Thus, the location of slices in one power plane may not be identical or practical of the power plane of another computer. Similarly, all hard disk drives are not necessarily identical. Thus, the location of slices in the power plane of one hard disk drive may not be identical or practical in the power plane of a different hard disk drive. However, the general concept of utilizing slices to change the resonance frequency of the power plane is applicable to any computer or hard disk drive power distribution network.

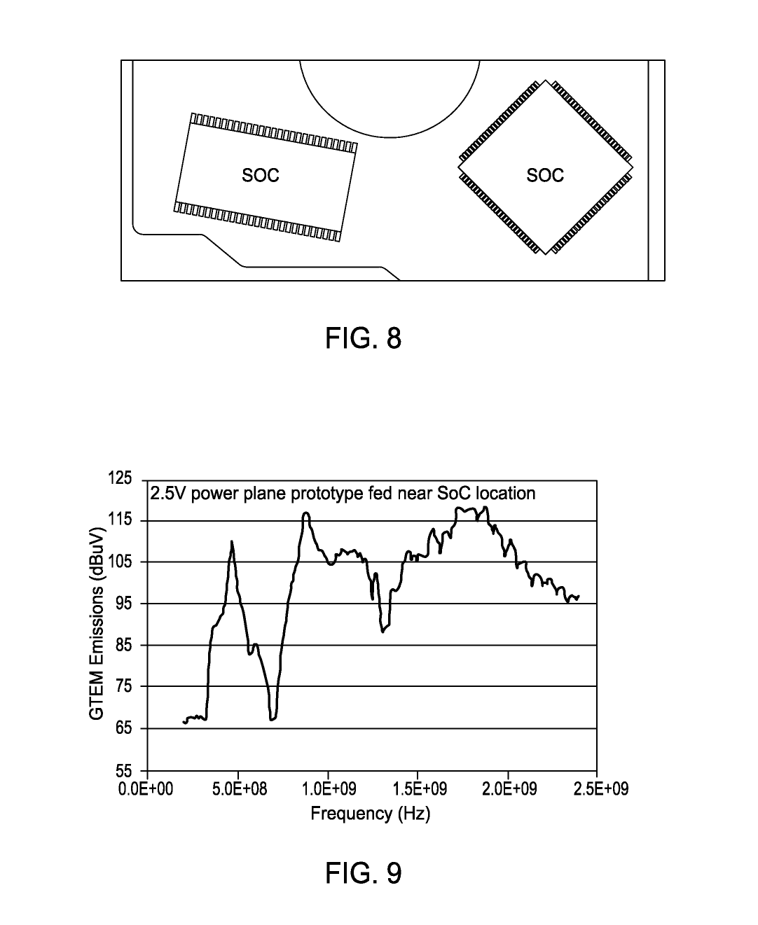

Not only may the geometry of the power distribution network affect the resonance frequency, but a device coupled to the printed circuit board may also affect the resonance frequency. For example, a system on chip (SOC) may be coupled to the printed circuit board and inject RF currents onto the power plane. FIG. 8 is a schematic illustration of a SOC coupled to a power plane having the same geometry as the power plane 202 in FIG. 2. FIG. 9 is a graph showing the Gigahertz Transverse ElectroMagnetic cell (GTEM) emissions or ElectroMagnetic Interference (EMI) for the SOC coupled to the power plane of FIG. 8. As shown in FIG. 9, the RF currents from the SOC excite resonances in the 2.5V power plane, including frequencies that interfere with GPRS and EDGE bands for 3G. The EMI is very large near and around the power plane resonances. The slices discussed above will correct the problem by shifting the resonance frequency and counteracting the effects of the SOC on the power plane.

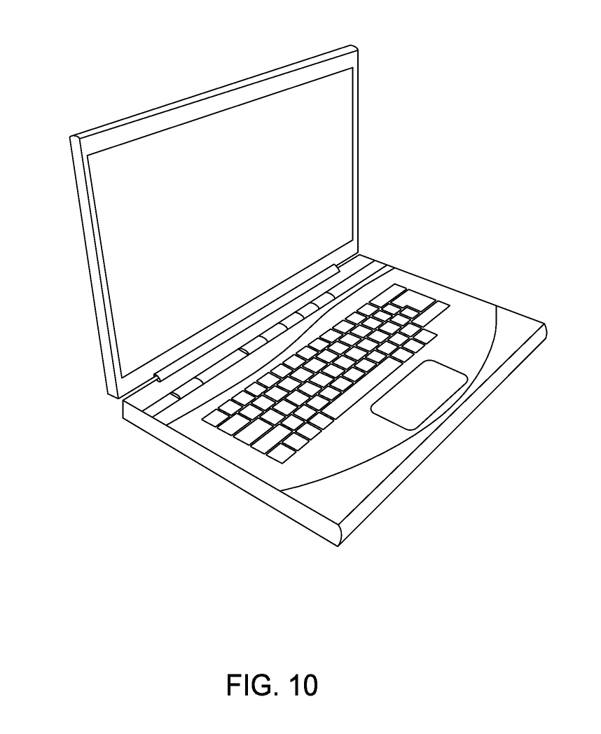

As discussed above, the slices may be present not only in the power plane, but also in the ground plane of a power distribution network. The slices may be utilized in any power distribution network even though discussed and shown as a power distribution network for a hard disk drive. For example, the power distribution network for a laptop computer, such as shown in FIG. 10, may have slices formed in either or both of the power plane or ground plane. The computer can include a hard disk drive employing the power distribution network discussed herein as well as a wireless card for receiving 3G signals.

The 3G source may include a 3G device is directly coupled to the printed circuit board and functions as a SOC. Alternatively, the 3G source may be a device that is inserted into and removed from the computer. The slices in the power distribution network may be at the point furthest away from the end where the power is connected to the power plane such that the slices are nearest the aggressor source (i.e., SOC or similar device). Alternatively, the slices may be present across the entire power/ground plane. Thus, it is envisioned that devices that would incorporate the slices technology include devices that have a wireless card and a power/ground plane that has the slices to create a resonance frequency of the power/ground plane that is outside the wireless card frequency bands. Suitable devices include a wireless card and one or more of a motherboard, a graphics card, or memory device.

It is to be understood that the embodiments discussed herein are applicable not only to a power distribution network for a hard drive, but also for a computer having a wireless card and a hard drive that each have a respective power distribution network that has slices to ensure the resonance frequency of the hard drive power plane is outside of the wireless card frequency bands. In another embodiment, the slices may simply be on a power distribution network coupled to a printed circuit board having a SOC or DRAM chip that emits within the wireless frequency range such that the SOC or DRAM chip is the aggressor and the power distribution network is the victim that needs to have its resonance frequency adjusted. The resonance frequency may be adjusted to ensure that the resonance frequency of the power/ground plane is more than 100 MHz above or below 1.8 GHz and more than 100 MHz above or below 900 MHz to ensure the power/ground plane does not interfere with the 3G wireless technology. In general, for forthcoming wireless technology (i.e., 4G, 5G, etc.), the resonance frequency of the power/ground plane can be adjusted to be more than 100 MHz above or below the wireless-card frequency band by placing slices into the power/ground plane. It is also to be understood that the slices may be on the power plane only, the ground plane only, or both the power plane and the ground plane.

While the foregoing is directed to embodiments of the present invention, other and further embodiments of the invention may be devised without departing from the basic scope thereof, and the scope thereof is determined by the claims that follow.

1. A PCB power/ground plane, comprising:
a main portion of the plane; and
a resonance modification element extending from the main portion provisioned with a plurality of interleaved and parallel openings to form a serpentine path from a first end of the element to a second end of the element, the configuration of the openings having been selected to achieve a desired resonance frequency different from a undesired resonance frequency produced by the modification element in the absence of the openings.

2. The PCB power/ground plane of claim 1, wherein the resonance frequencies of the new resonance modification element is altered more than 100 MHz about the original resonance frequencies.

3. The PCB power/ground plane of claim 1, wherein the resonance frequency of the new resonance modification element is more than 100 MHz above or below 1.8 GHz.

4. The PCB power/ground plane of claim 3, wherein the resonance frequency of the new resonance modification element is more than 100 MHz above or below 900 MHz.

5. The PCB power/ground plane of claim 4, wherein the PCB power/ground plane is disposed within a hard disk drive.

6. The PCB power/ground plane of claim 1, wherein the resonance frequency of the new resonance modification element is more than 100 MHz above or below 900 MHz.

7. The PCB power/ground plane of claim 6, wherein the PCB power/ground plane is disposed within a hard disk drive.

8. The PCB power/ground plane of claim 1, wherein the PCB power/ground plane is disposed within a hard disk drive.

9. A device, comprising:
a wireless card configured to operate at a wireless frequency; and
a power/ground plane comprising a body extending from a first end to a second end, wherein the body has a plurality of interleaved slices formed therein to create a serpentine pattern that alters the resonance frequency of the body relative to the resonance frequency of the body in absence of the plurality of interleaved slices, and wherein the resonance frequency is outside the wireless frequency.

10. The device of claim 9, wherein the resonance frequency of the power/ground plane is more than 100 MHz above or below 1.8 GHz.

11. The device of claim 10, wherein the resonance frequency of the power/ground plane is more than 100 MHz above or below 900 MHz.

12. The device of claim 9, wherein the resonance frequency of the power/ground plane is more than 100 MHz above or below 900 MHz.

13. The device of claim 12, further comprising a SOC chip coupled to the power/ground plane.

14. The device of claim 13, wherein the plurality of interleaved slices are closer to the SOC chip than to a location where power is coupled to the power/ground plane.

15. A device, comprising:
a wireless card; and
a hard disk drive having a power/ground plane, comprising a body extending from a first end to a second end, wherein the body has a plurality of interleaved slices formed therein to create a serpentine pattern that alters the resonance frequency of the body relative to the resonance frequency of the body in absence of the plurality of interleaved slices.

16. The device of claim 15, wherein the resonance frequency of the power/ground plane is more than 100 MHz above or below 1.8 GHz.

17. The device of claim 16, wherein the resonance frequency of the power/ground plane is more than 100 MHz above or below 900 MHz.

18. The device of claim 17, further comprising a SOC chip coupled to the power/ground plane.

19. The device of claim 18, wherein the plurality of interleaved slices are closer to the SOC chip than to a location where power is coupled to the power/ground plane.

20. The device of claim 15, wherein the resonance frequency of the power/ground plane is more than 100 MHz above or below 900 MHz.

21. The device of claim 15, further comprising a SOC chip coupled to the power/ground plane, wherein the plurality of interleaved slices are closer to the SOC chip than to a location where power is coupled to the power/ground plane.
